(19) United States
(12) Patent Application Publication
(10) Pub. No.: US 2026/0090259 A1
(43) Pub. Date: Mar. 26, 2026

(54) ALL-INORGANIC PEROVSKITE-BASED SHORT-WAVE INFRARED PHOTODETECTORS AND PROCESSES FOR FORMING

(71) Applicants: Honda Motor Co., Ltd., Tokyo (JP); Utah State University, Logan, UT (US)

(72) Inventors: Gugang CHEN, Palo Alto, CA (US); Yi RAO, Logan, UT (US)

(21) Appl. No.: 18/897,597

(22) Filed: Sep. 26, 2024

(51) Int. Cl. H10K 71/40; H10K 30/10; H10K 30/86; H10K 85/10

(52) U.S. Cl. CPC H10K 71/40; H10K 30/10; H10K 30/86; H10K 85/113

(57) ABSTRACT

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors. In an aspect is provided a composition that includes a nitrogen-containing compound and an all-inorganic perovskite. In an aspect, a process for forming a SWIR device is provided. The process includes forming a precursor solution comprising: a first compound (AX), a second compound, a nitrogen-containing compound or ion thereof, and a solvent. The process further includes dispersing the precursor solution on a substrate, annealing the dispersed precursor solution on the substrate by heating to form a film composition comprising: the nitrogen-containing compound or ion thereof; and an all-inorganic perovskite represented by Formula (I): ABX₃ (I).

### FIELD

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors.

### BACKGROUND

SWIR light is finding widespread use in both civilian and military contexts, including inspection processes, nighttime imaging, and machine vision. As such, there is increasing demand for practical and effective SWIR detectors. Conventional SWIR sensors are based primarily on indium gallium arsenide (InGaAs). However, InGaAs is expensive and requires cryogenic conditions to achieve its noted specific detectivity and responsivity characteristics. More recently, lead-based perovskites have been used as photodetectors in the ultraviolet to near infrared ranges. However, the large bandgaps of conventional lead-based perovskites limit their use for lower energy SWIR light. In addition, conventional SWIR materials are unstable and require complex fabrication processes.

There is a need for new compositions for detecting SWIR light, devices for detecting SWIR light, and to photodetectors for detecting SWIR light. There is also a need for new processes for forming such compositions, devices, and photodetectors.

### SUMMARY

Aspects of the present disclosure generally relate to a new class of compositions utilized for detecting SWIR light and to devices, such as photodetectors, that include the compositions. Aspects of the present disclosure also generally relate to processes for forming such compositions, devices, and photodetectors. In contrast to conventional technologies, compositions described herein include an all-inorganic perovskite, a nitrogen-containing compound, and an optional mineral acid.

Unlike conventional SWIR photodetectors, SWIR photodetectors of the present disclosure may be characterized as having high responsivity and/or high specific detectivity under ambient conditions (for example, at room temperature). Moreover, compositions and photodetectors described herein have improved chemical stability and long-term stability over conventional technologies. Improved processes for forming the compositions and photodetectors are also described herein. For example, the inventors found a scalable and efficient solution-based fabrication process for fabricating, e.g., a thin film of the composition and fabricating devices such as photodetectors that include the composition. Traditional methods for making SWIR compositions and photodetectors, in contrast, are expensive.

Compositions of the present disclosure have unique light absorbance wavelengths from, for example, the visible to SWIR bands. Compositions described herein may be incorporated into devices for detecting, sensing, localizing, and/or imaging various objects by SWIR light or radiation. Aspects described herein may find applications in, for example, automobiles, remote sensing, vehicle control, automated inspection, identifying and sorting, surveillance, anti-counterfeiting, and environmental chemical analysis, among other applications.

In an illustrative, but non-limiting, example, the inventors found an all-inorganic photodetector that includes cesium lead iodide (CsPbI₃), hydrazinium iodide, and optionally hydroiodic acid for detection in the SWIR range. Aspects described herein show high specific detectivity at room temperature in ambient air. Aspects described herein show high responsivity and high sensitivity, distinguishing aspects of the present disclosure from conventional technologies in the field of SWIR photodetection.

In an aspect, a process for forming a SWIR device is provided. The process includes forming a precursor solution comprising: a first compound (AX) comprising a monovalent metal cation (A) and a first monovalent anion (X); a second compound (BX₂) comprising a divalent metal (B) and two second monovalent anions (X), each X being the same or different; a nitrogen-containing compound or ion thereof; and a solvent. The process further includes dispersing the precursor solution on a substrate. The process further includes annealing the dispersed precursor solution on the substrate by heating the substrate at an annealing temperature that is from about 50° C. to about 170° C. to form a film composition comprising: the nitrogen-containing compound or ion thereof; and an all-inorganic perovskite represented by Formula (I): ABX₃ (I).

In another aspect a composition is provided that includes: a nitrogen-containing compound or ion thereof; and an all-inorganic perovskite represented by Formula (I): ABX₃ (I), wherein: A of Formula (I) is a monovalent metal or ion thereof; B of Formula (I) is a divalent metal or ion thereof; and each X of Formula (I) is a halogen or ion thereof, each X of Formula (I) being the same or different.

In another aspect a SWIR detector is provided. The SWIR detector includes a thin film comprising a composition, the thin film comprising: a nitrogen-containing compound or ion thereof; and an all-inorganic perovskite represented by Formula (I): CsPbX₃ (I), wherein each X of Formula (I) is a halogen or ion thereof, each X of Formula (I) being the same or different; and wherein a molar ratio of the nitrogen-containing compound or ion thereof to the all-inorganic perovskite in the composition is from about 0.5:1 to about 4:1.

### BRIEF DESCRIPTION OF THE DRAWINGS

So that the manner in which the above recited features of the present disclosure may be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, for the disclosure may admit to other equally effective aspects.

FIG. 1 is a schematic of a device fabrication process.

FIG. 2 is a schematic of a photodetector device with poly(3,4-ethylenedioxythiophene) polystyrene sulfonate and a composition that includes a CsPbI₃ perovskite on fluorine-doped tin oxide-coated glass.

FIG. 3 is an energy level diagram of a photodetector device, showing the highest occupied molecular orbital (HOMO) and the lowest unoccupied molecular orbital (LUMO) of each component in electron-volts.

FIG. 4 is an absorption spectrum of a coated device from 2500 nm to 400 nm.

FIG. 5 shows photoresponsivity curves at various power levels of 1310 nm illumination.

FIG. 6 shows responsivity at biases from −1 volt (V) to −5 V as a function of incident light power density forms parallel lines of negative slope.

FIG. 7 shows data for current through the device with 1310 nm light on and off under a bias of 3 V. The current has been corrected such that the light-off current is about 0 amperes for comparison.

FIG. 8 is a plot showing maximum photocurrent at each light intensity indicating a strong positive, linear relationship.

### DETAILED DESCRIPTION

Aspects of the present disclosure generally relate to a new class of compositions utilized for detecting short-wave infrared (SWIR) light, to devices including the compositions, and to photodetectors including the compositions. As used herein, a “composition” may include component(s) of the composition, reaction product(s) of two or more components of the composition, and/or a remainder balance of remaining starting component(s), or combinations thereof. Aspects of the present disclosure also generally relate to processes for forming the compositions, the devices, and the photodetectors.

SWIR light, having wavelengths from about 700 nanometers and 2,500 nanometers, has become important in many applications. SWIR light has found myriad uses in remote sensing, communications, spectroscopy, security, and many hyperspectral imaging processes. SWIR imaging is able to penetrate harsh weather conditions like fog better than visible light. Additionally, machine vision in the SWIR range is important in military applications for the discrimination of camouflaged materials and even the detection of landmines and chemical warfare agents. As such, practical, affordable, and sensitive SWIR photodetectors are needed.

InGaAs is currently the dominant SWIR detector material, exhibiting responsivity greater than 6.5×10³ A/W at 1550 nm with specific detectivity on the order of 10¹² Jones. However, its high cost and requirement of cryogenic conditions to achieve the noted results warrant the search for new SWIR detection materials. Colloidal quantum dot detectors are an emerging candidate for SWIR applications due to their tunable spectral properties and low cost. However, their quantum efficiency and charge transport are low compared to other detectors. Graphene-based technologies possess many attractive qualities as SWIR detectors. Due to its near-zero bandgap, graphene exhibits broadband absorption into the far infrared with fast response and high carrier mobility. However, its very low light absorption of 2.3% limits its responsivity to the milliAmpere per Watt (mA/W) scale.

Perovskites, materials having the general form ABX₃ where X is a halogen anion, are another promising candidate in the field of SWIR photodetection. Perovskite photodetectors (PPDs) exhibit notable characteristics including a tunable bandgap, high carrier mobility, and simple, solution-based coating processes. Organic-inorganic PPDs, notably methylammonium lead triiodide (MAPbI₃) PPDs have repeatedly shown effective response in the ultraviolet (UV) to near infrared (NIR) (about 300-800 nm) regions but with highly variable responsivity (R), detectivity (D*) and external quantum efficiency (EQE). However, the wide bandgap of these perovskite materials limits response to longer wavelengths outside of the SWIR range. Additionally, organic-inorganic hybrid PPDs suffer from instability in the presence of oxygen and moisture, making broader application of organic-inorganic hybrid PPDs difficult.

Conversely, all-inorganic lead halide perovskites offer superior stability by replacing methylammonium with cesium (Cs). Conventional Cs-based inorganic PPDs have shown high temperature tolerance, maintaining 70% photodetection ability under 373 K heat after 9 hours, showing promise for real-world use. However, Cs-based inorganic PPDs are blind to wavelengths greater than 430 nm, limiting their use to only the ultraviolet to near-infrared ranges, well below the SWIR range.

Thus, there is a need for perovskite-containing compositions that have a decreased bandgap and usefulness in the SWIR regime. To overcome, at least, the aforementioned shortcomings, the inventors found various compositions that may be utilized for photodetection in the SWIR range. In some examples, compositions utilized for photodetection in the SWIR range may include an all-inorganic CsPbI₃ perovskite, hydrazinium iodide, and hydroiodic acid. The inventors developed a scalable and efficient synthesis of the composition. The inventors also developed an ambient-condition coating process to form effective SWIR photodetectors with a perovskite-containing composition using a fluoride-doped tin oxide-glass device as a substrate and poly(3,4-ethylenedioxythiophene) polystyrene sulfonate as a hole transport layer. The device achieved unexpectedly high responsivity and external quantum efficiency measured at room temperature.

Aspects of the present disclosure generally relate to processes for forming compositions that include an all-inorganic perovskite and a nitrogen-containing compound. The composition may further include a mineral acid. Such compositions may be utilized as a SWIR material. The compositions may be in the form of a film such as a thin film. In some aspects, the process includes forming a precursor solution that includes metal compounds, adding an additive (e.g., a nitrogen-containing compound) to the precursor solution, dispersing the resultant precursor solution on a substrate, and annealing the dispersed precursor solution on the substrate.

The all-inorganic perovskite of the composition may be represented by Formula (I):

ABX₃ (I),
wherein:
A of Formula (I) is a monovalent metal or ion thereof;
B of Formula (I) is a divalent metal or ion thereof; and
each X of Formula (I) is a halogen or ion thereof, each X of Formula (I) being the same or different.

A process for forming a composition may include forming a mixture comprising: a first compound AX (or A⁺X⁻) that includes a monovalent metal A (or A⁺) and a first monovalent anion X (or X⁻); a second compound BX₂ comprising a divalent metal B (or B⁺) and two second monovalent anions X (or X⁻); and a nitrogen-containing compound.

Each X (or X⁻) may be the same or different. For example the X of AX may be the same or different from each X of BX₂. Additionally, or alternatively, each X of BX₂ may be the same or different. The first compound and/or the second compound may include metal salts.

The monovalent metal A (or cation A⁺) of the first compound may include an alkali metal (e.g., cesium (Cs), potassium (K), sodium (Na), lithium (Li)), a transition metal (e.g., silver (Ag), gold (Au), copper (Cu), and/or a cation thereof. The first monovalent anion X (or X⁻) of the first compound may include a halogen (or ion thereof) such as fluorine (F), chlorine (Cl), bromine (Br), or iodine (I), such as Cl, Br, or I, such as Br or I. Examples of first compounds may include, but are not limited to, CsI, CsCl, CsBr, KCl, KBr, KI, NaCl, NaBr, NaI, LiCl, LiBr, LiI, AgCl, AgBr, AgI, CuCl, CuBr, CuI, AuCl, AuBr, AuI, or combinations thereof.

The divalent metal B (or cation B⁺) of the second compound may include an alkali earth metal (e.g., beryllium (Be), magnesium (Mg), calcium (Ca), strontium (Sr), barium (Ba), or radium (Ra)), a Group 3-15 metal of the periodic table of the elements (e.g., lead (Pb), mercury (Hg), cadmium (Cd), arsenic (As), chromium (Cr), thallium (Tl), and/or a cation thereof. The two second monovalent anions X (or X⁻) of the second compound may include a halogen (or ion thereof) such as fluorine (F), chlorine (Cl), bromine (Br), or iodine (I), such as Cl, Br, or I, such as Br or I. Examples of second compounds may include, but are not limited to, PbI₂, HgI₂, CdI₂, or combinations thereof.

Any suitable nitrogen-containing compound or ion thereof may be utilized. Illustrative, but non-limiting, examples of nitrogen-containing compounds may include hydrazine, ammonia, methylamine, dimethylamine, trimethylamine, ethylamine, diethylamine, triethylamine, triisopropylamine, aziridine, diaziridine, formamidine, amidine, guanidine, or combinations thereof. Illustrative, but non-limiting, examples of ions of nitrogen-containing compounds may include hydrazinium, ammonium, methylammonium, dimethylammonium, trimethylammonium, ethylammonium, diethylammonium, triethylammonium, triisopropylammonium, aziridinium, diaziridinium, formamidinium, amidinium, guanidinium, or combinations thereof. Nitrogen-containing compounds may include salts, such as halide salts, of such ions. An illustrative, but non-limiting, example of a nitrogen-containing compounds may include hydrazinium iodide, ([NH₂NH₃⁺I⁻], HAI)

The nitrogen-containing compound may include a protonated nitrogen atom (such as a nitrogen atom with a formal charge of +1) such that the nitrogen-containing compound comprises a cationic group. The nitrogen-containing compound may optionally include any suitable counter anion such as a halogen, such as Cl, Br, or I, such as I or Br. The nitrogen-containing compound may be made by protonating a nitrogen-containing compound with an acid or other material, such as hydrochloric acid (HCl), hydrobromic acid (HBr), hydroiodic acid (HI), or combinations thereof. A non-limiting example of a suitable nitrogen-containing compound may include hydrazinium iodide (NH₂NH₃I).

The process for forming the composition may further introduction of a mineral acid to the mixture comprising the first compound, the second compound, and the nitrogen-containing compound. The mineral acid may include hydroiodic acid (HI), hydrochloric acid (HCl), nitric acid (HNO₃), phosphoric acid (H₃PO₄), sulfuric acid (H₂SO₄), hydrobromic acid (HBr), perchloric acid (HClO₄), or combinations thereof.

Aspects of the present disclosure also relate to processes for forming a SWIR device. The process for forming a SWIR device may include forming a precursor solution that includes: (a) a first compound (AX) comprising a monovalent metal cation (A) and a first monovalent anion (X); (b) a second compound (BX₂) comprising a divalent metal (B) and two second monovalent anions (X), each X being the same or different; (c) a nitrogen-containing compound or ion thereof; and (d) a solvent. Non-limiting examples of the first compound, the second compound, and the nitrogen-containing compound (or ion thereof) are described above.

Any suitable solvent, or solvent mixture, may be utilized for the precursor solution. Non-limiting examples of suitable solvents may include organic solvents such as, dimethylformamide, dimethylsulfoxide, gamma-butyrolactone, tetrahydrofuran, or combinations thereof. The solvent or solvent mixture may be anhydrous.

In at least one aspect, a solvent mixture is utilized for the precursor solution. For example, a solvent mixture comprising a first solvent, a second solvent, and a third solvent may be utilized. A volume ratio of the first solvent to the second solvent may be from about 5:1 to about 15:1, such as from about 6:1 to about 14:1, such as from about 8:1 to about 12:1, such as from about 9:1 to about 11:1, such as about 10:1. A volume ratio of the first solvent to the third solvent may be from about 80:1 to about 100:1, such as from about 85:1 to about 95:1, such as from about 86:1 to about 94:1, such as from about 88:1 to about 92:1, such as from about 89:1 to about 91:1, such as from about 90:1. A volume ratio of the second solvent to the third solvent may be from about 5:1 to about 13:1, such as from about 6:1 to about 12:1, such as from about 8:1 to about 10:1, such as about 9:1.

In a non-limiting example, the first solvent may be DMF, the second solvent may be DMSO, and the third solvent may be GBL, and a volume ratio of the DMF:DMSO:GBL may be about 90:9:1.

The precursor solution may include an amount of the second compound (BX₂) in the solvent that is from about 0.1 M to about 1 M, such as from about 0.3 M to about 0.8 M, such as about 0.5 M. The precursor solution may include a molar ratio of the first compound (AX) plus the nitrogen-containing compound to the second compound (AX+nitrogen-containing compound :BX₂) that is from about 0.5:1 to about 4:1, such as from about 1:1 to about 3:1, such as about 2:1.

The process for forming the SWIR device may optionally include introduction of a mineral acid with the precursor solution. Non-limiting examples of mineral acids are described above. The precursor solution may include a molar ratio of the hydroiodic acid or ion thereof to first compound (AX) in the precursor solution is from about 0.01:1 to about 5:1, such as from about 0.1:1 to about 1:1, or from about 0.2:1 to about 2:1.

A molar ratio of the first compound (AX) plus the nitrogen-containing compound to the second compound (BX₂) in the precursor solution may be from about 0.5:1 to about 4:1, such as from about 1:1 to about 3:1, such as about 2:1. For example, a molar ratio of (CsI+HAI):PbI₂ may be about 2:1.

The process for forming the SWIR device may further include dispersing the precursor solution onto a substrate and/or a hole transport layer (HTL). Any suitable substrate may be utilized such as glass, sapphire, polymer, or fluorine-doped tin oxide (FTO)-coated glass. The substrate may be a flexible material or an inflexible material. For example, glass, sapphire, FTO-coated glass, or a flexible polymer may be utilized as the substrate. The HTL may be made of, or include, any suitable material such as poly(3,4-ethylenedioxythiophene) polystyrene sulfonate (PEDOT:PSS).

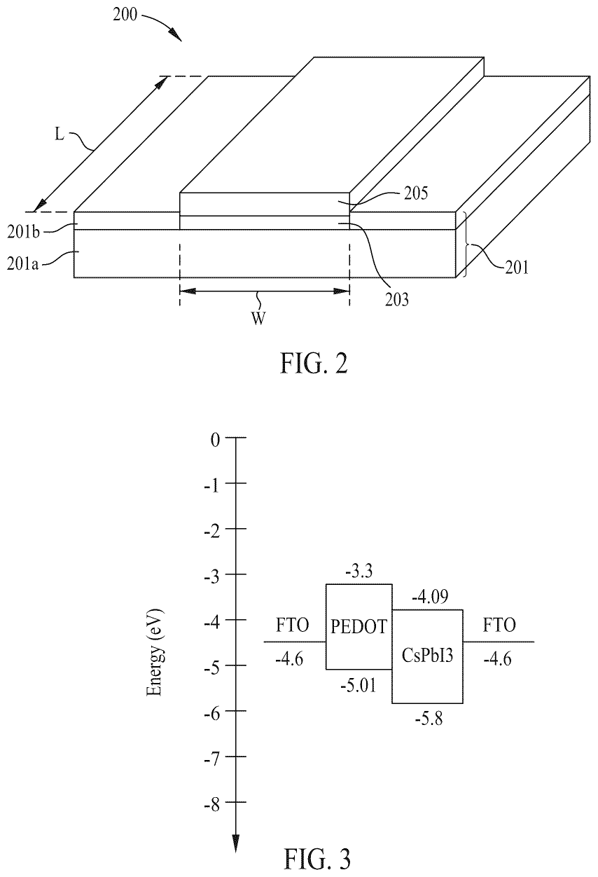

An aspect of the formed device is shown in FIG. 2, further described below. As shown, the substrate 201 may include a first layer 201a (for example, glass) and a second layer 201b (for example, FTO layer) disposed over at least a portion of the first layer 201a. The second layer 201b has a trench. The HTL 203 may be disposed within the trench of the second layer 201b and over a portion of the first layer 201a, such that sidewalls of the HTL 203 are adjacent with sidewalls of the second layer 201b. The precursor solution is dispersed onto the HTL 203 such that a thin film of the composition (a perovskite-containing layer 205) forms on the HTL 203.

Although the device is shown such that the thin film of the composition (perovskite-containing layer 205) is formed on the HTL 203 during processes for forming an SWIR device, it is contemplated that the thin film may be formed on the substrate during processes for forming an SWIR device. That is, the precursor solution may be dispersed onto the substrate, the HTL, or combinations thereof.

In the description for processes for forming an SWIR device (e.g., a SWIR photodetector), reference to substrate includes reference to both substrate and HTL unless specified to the contrary or the context clearly indicates otherwise. For example, dispersing the precursor solution onto the substrate refers to dispersing the precursor solution onto the substrate and/or onto the HTL (if present).

During the dispersing the precursor solution onto the substrate, the substrate may be kept at about ambient room temperature (e.g., from about 15° C. to about 25° C.) or may be heated utilizing a chuck.

The precursor solution may be dispersed onto the substrate by any suitable means to form a thin film of precursor solution on the substrate. A non-limiting example of dispersing is chemical solution deposition. In general, chemical solution deposition is a process for depositing thin films on a substrate surface and/or a HTL surface by chemical reaction or electrochemical reaction to form a film. Chemical solution deposition may be utilized to accurately control the stoichiometric ratio and provide a film with good uniformity. A non-limiting example of chemical solution deposition that may be utilized includes spin-coating. Spin-coating includes spinning (or rotating) the substrate at a suitable speed and dispersing the precursor solution onto the rotating substrate. For example, the precursor solution may form a thin film on a rotating substrate.

The substrate may be rotated at a suitable speed to disperse the precursor solution (and form a thin film of precursor solution) but not at such an excessive speed to dislodge the precursor solution from the substrate. Suitable rotation speeds may include 100 revolutions per minute (rpm) or more, 4,000 rpm or less, or combinations thereof, such as from about 100 rpm to about 4,000 rpm, such as from about 500 rpm to about 3,500 rpm, such as about 1,000 rpm to about 3,000 rpm, such as from about 1,500 rpm to about 2,500 rpm, such as about 2,000 rpm.

The substrate may be rotated at a suitable angular acceleration that is about 100 radians per second squared (rad/s²), about 2,000 rad/s² or less, or combinations thereof, such as from about 100 rad/s² to about 2,000 rad/s², such as from about 300 rad/s² to about 1,800 rad/s², such as from about 500 rad/s² to about 1,500 rad/s², such as from about 800 rad/s² to about 1,200 rad/s², such as about 1,000 rad/s².

The precursor solution may be dispersed onto the substrate for a period of about 1 second or more, about 20 minutes or less, or combinations thereof, such as from about 1 second to about 20 minutes, such as from about 5 seconds to about 10 minutes, such as from about 10 seconds to about 5 minutes, such as from about 20 seconds to about 5 minutes, such as from about 30 seconds to about 1 minute, such as about 45 seconds, or from about 5 seconds to about 1 minute such as about 30 seconds to about 45 seconds.

Optionally, spin-coating may be performed in a glove box, under a non-reactive gas (such as N₂ or Ar), or combinations thereof.

Prior to dispersing the precursor solution onto the substrate, the precursor solution may be optionally pre-heated. The precursor solution comprising the first compound, second compound, nitrogen-containing compound, solvent, and the optional mineral acid may be optionally pre-heated at a precursor solution pre-heating temperature that is from about 40° C. to about 110° C., such as from about 50° C. to about 100° C., such as from about 60° C. to about 90° C., such as from about 70° C. to about 80° C., such as about 75° C.

Pre-heating of the precursor solution prior to dispersing the precursor solution on the substrate may affect the crystallization rate of the composition. For example, pre-heating the precursor solution may cause the solvent in the precursor solution to evaporate more quickly, which may increase the nucleation density and increase crystal perovskite strength, resulting in better film quality. This better film quality may have higher light absorption efficiency, and when the film is in a device, the current of the device may be increased. Additionally, the pre-heating of the precursor solution may advantageously affect the photoelectric performance, such as specific detectivity and responsivity, of the resulting device.

Under the spin-coating process, and as described above, appropriate pre-heating temperatures may promote crystallization and the formation of a uniform film with good photoelectric performance. In addition, the inventors found that various conditions of the spin-coating process may have a significant impact on the resulting performance characteristics such as responsivity and specific detectivity of the resulting device, e.g., photodetector. For example, higher or lower annealing temperatures may reduce performance characteristics. As another example, faster or slower rotation of the substrate during spin-coating may reduce responsivity and specific detectivity.

The process for forming the SWIR device may further include annealing the dispersed solution upon the substrate. A purpose of the annealing may include forming a pure-phase substance, eliminating excess material. The pure-phase substance may also promote continuous growth of grains and an increase in size, further improving the stability of the film. In some aspects, a thin film of precursor solution is annealed on the substrate. According to some aspects, depending on the annealing conditions, and for example, the chemical composition of the precursor solution, the wavelength of maximum SWIR absorbance of the resulting composition comprising the perovskite may change. Annealing may optionally be performed under vacuum conditions.

Annealing may be performed at an annealing temperature that is from about 50° C. to about 170° C., such as from about 70° C. to about 150° C., such as from about 80° C. to about 140° C., such as from about 90° C. to about 130° C., such as from about 100° C. to about 120° C., such as about 110° C. Annealing may be performed for any suitable period. Non-limiting examples of annealing times are from about 1 minute to about 60 minutes, such as from about 10 minutes to about 50 minutes, such as from about 20 minutes to about 40 minutes, such as about 30 minutes.

The annealing forms a composition that includes an all-inorganic perovskite represented by Formula (I), a nitrogen-containing compound, and an optional mineral acid. This composition which may be in the form of a film may be utilized as a SWIR material.

The inventors found that the molar ratio (MR) of the nitrogen-containing compound to the first compound plus the nitrogen-containing compound in the precursor solution (see Eq. 1) may be operative to (or adapted to) determine a wavelength of maximum SWIR absorbance of the film.

$$MR = \frac{{NH}_{2} {NH}_{3} I}{CsI + {NH}_{2} {NH}_{3} I} \qquad ( Eq . 1 )$$

wherein: NH₂NH₃I in Eq. 1 is molar amount of hydrazinium iodide in the precursor solution; CsI in Eq. 1 is molar amount of cesium iodide in the precursor solution; and % value in Eq. 1 is a mol/mol % value. The mol/mol % value may be those values described above.

For example, and in some aspects, a higher molar ratio for Eq. 1 may provide a composition with a higher wavelength of maximum SWIR absorbance than a composition with a lower molar ratio. That is, aspects described herein may be utilized to tune wavelengths of maximum SWIR absorbance of the films and thereby use the SWIR materials in various applications. The molar ratio as determined by Eq. 1 may be from about 0.1:1 to about 1:1, such as from about 0.2:1 to about 0.5:1, such as about 1:1.

A non-limiting example procedure for forming a device described herein may be performed as follows: A precursor solution may be prepared by dissolving the first compound and the second compound in a solvent. The nitrogen-containing compound (e.g., NH₂NH₃I) and optional mineral acid may be added to the precursor solution. The resultant precursor solution may be pre-heated to a temperature of about 60° C. to about 90° C. A substrate with an HTL thereon may be placed on a spin-coater chuck. The precursor solution may then be spin-coated on the HTL for a period of about 1 minute or less while rotating the substrate at about 1,000 rpm to about 3,000 rpm. The spin-coated substrate may then be annealed, under vacuum, at an annealing temperature that is from about 80° C. to about 140° C. for a period of about 10 minutes to about 1 hour. The resulting thin film comprising the all-inorganic perovskite, the nitrogen-containing compound, and the optional mineral acid may then be allowed to cool.

Aspects of the present disclosure also generally relate to compositions that include an all-inorganic perovskite and a nitrogen-containing compound or ion thereof. The composition optionally includes a mineral acid. The compositions may be in the form of a film such as a thin film. Such compositions and films thereof may be utilized as a SWIR material.

The all-inorganic perovskite of compositions described herein may be represented by Formula (I) (ABX₃) as described above. Non-limiting examples of the nitrogen-containing compound (or ion thereof) and non-limiting examples of mineral acids are also described above.

In some aspects of Formula (I): A is Cs; B is Pb; and each X is, independently, I, Br, Cl, or combinations thereof, such as I.

A molar ratio of the nitrogen-containing compound or ion thereof to the first compound plus the nitrogen-containing compound or ion thereof in the composition may be from about 0.05:1 to about 2:1, such as from about 0.1:1 to about 1:1, such as from about 0.2:1 to about 0.5:1. For example, a molar ratio of (HAI)/(CsI+HAI) may be about 15%.

A molar ratio of the mineral acid (such as HI) to the all-inorganic perovskite in the composition may be from about from about 0.01:1 to about 5:1, such as from about 0.1:1 to about 1:1, or from about 0.2:1 to about 2:1.

A molar ratio of the nitrogen-containing compound or ion thereof to the all-inorganic perovskite in the composition may be from about 0.5:1 to about 4:1, such as from about 1:1 to about 3:1, such as about 2:1.

The composition may have a highest SWIR absorption at room temperature that is from about 700 nm to about 2800 nm, such as from about 1000 nm to about 2800 nm, such as from about 700 nm to about 1800 nm, such as from about 700 to about 1500 nm, such as from about 800 nm to about 1400 nm, such as from about 900 nm to about 1300 nm, such as from about 1000 nm to about 1200 nm, such as from about 1100 to about 1150, such as from about 1120 to about 1140, such as about 1130 to about 1135, such as about 1132 nm. It is noted that the highest SWIR absorption at room temperature may be different.

Compositions described herein may be in the form of films. The films may be utilized as a SWIR material. Films described herein may have any suitable thickness. In some aspects, a film described herein has a thickness that is from about 5 nm to about 2,000 nm (about 2 μm), such as from about 10 nm to about 1,750 nm (about 1.75 μm), such as from about 100 nm to about 1000 nm (about 1 μm), such as from about 125 nm to about 900 nm, such as from about 150 to about 800 nm, such as from about 200 nm to about 700 nm, such as from about 250 nm to about 600 nm, such as from about 300 nm to about 500 nm, or from about 150 nm to about 250 nm, such as about 200 nm, though other values are contemplated. Any of the foregoing numbers may be used singly to describe an open-ended range or in combination to describe a close-ended range.

Aspects described herein may be used in various applications including imaging, sensing, security, and electronic applications such as produce inspection, electronic board inspection, identifying and sorting, surveillance, anti-counterfeiting, process quality control, among others. Aspects described herein may find applications in, for example, automobiles, remote sensing, vehicle control, automated inspection, identifying and sorting, surveillance, anti-counterfeiting, and environmental chemical analysis, among other applications.

The following examples are put forth so as to provide those of ordinary skill in the art with a complete disclosure and description of how to make and use aspects of the present disclosure, and are not intended to limit the scope of aspects of the present disclosure. Efforts have been made to ensure accuracy with respect to numbers used (for example, amounts, dimensions, etc.) but some experimental errors and deviations should be accounted for.

### EXAMPLES

Examples of compositions and devices (e.g., photodetectors) described herein were made using various materials set out in the Materials and are described further below.

### Materials

Poly(3,4-ethylenedioxythiophene) polystyrene sulfonate (PEDOT:PSS) solution was obtained from Heraeus Epurio. Anhydrous dimethylformamide (DMF) was obtained from Supelco. Lead iodide (PbI₂), hydrazine (NH₂NH₂), anhydrous dimethylsulfoxide (DMSO), and gamma-butyrolactone (GBL) were obtained from Sigma Aldrich. Cesium iodide (CsI) and hydroiodic acid (HI, 57% w/w aqueous solution stabilized with 1.5% hypophosphorous acid (H₃PO₂)) were obtained from Alfa Aesar. All chemicals were used as received without further purification.

### Example 1: Hydrazinium Iodide Preparation

Hydrazinium iodide (NH₂NH₃I, also referred to as HAI) was used as a non-limiting example of a nitrogen-containing compound. HAI was prepared by mixing hydrazine and hydroiodic acid at a temperature of about 0° C. The hydrazine solution diluted with ethanol (50%) was added into the hydroiodic acid solution slowly until a precipitate formed. The precipitate was recrystallized from cooled ethanol to yield NH₂NH₃I (HAI) as a snow-white powder.

### Example 2: SWIR Device Fabrication

A SWIR device was fabricated using the following general operations: (1) preparation of FTO-coated glass for PEDOT:PSS coating; (2) PEDOT:PSS coating process; (3) preparation of precursor solution, and (4) sample coating process.
(1) Preparation of FTO for PEDOT:PSS Coating and (2) PEDOT:PSS Coating Process

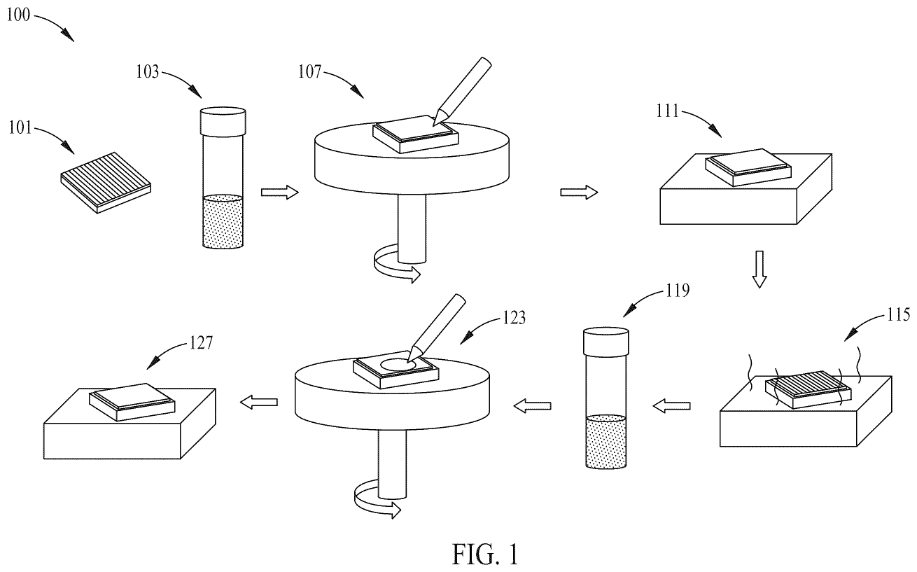

An FTO-coated glass device was utilized as a substrate and PEDOT:PSS was utilized as the hole transport layer (HTL). FIG. 1 is a schematic of a device fabrication process.

A FTO-coated glass substrate (50 μm) was cleaned using Piranha solution (a mixture of concentrated sulfuric acid with hydrogen peroxide, in a ratio of 3:1 to 7:1) for 30 minutes before rinsing thoroughly and being stored in ethanol and/or isopropanol. Before PEDOT:PSS coating, the substrate was dried under air stream and cleaned for 30 minutes in an Ossila UV-ozone cleaner to provide the cleaned patterned FTO glass 101.

A PEDOT:PSS solution in a vial was sonicated (operation 103) in a glass vial for at least 30 minutes. After sonication, the substrate (the cleaned patterned FTO glass 101) was spin-coated (operation 107) at 3500 revolutions per minute (rpm) for 30 seconds, depositing 150 μL of PEDOT:PSS in the center of the substrate as shown in FIG. 1. The PEDOT:PSS-coated substrate was transferred to an oven where it was annealed (operation 111) at 145° C. for 30 minutes under vacuum, then cooled to room temperature.

### (3) Preparation of Precursor Solution

Prior to formation of the thin film containing the perovskite, the sample (in the form of a precursor solution) included 0.5 M PbI₂, with 2:1 (CsI+HAI):PbI₂ and HAI/(CsI+HAI)=15% in 9:1 DMF:(9:1 DMSO:GBL) with the addition of 40 μL of HI per 1 mL of sample solution added 5 minutes before coating.

PbI₂ (115.3 mg), CsI (110.3 mg), HAI (12.0 mg, synthesis described above), 450 μL of anhydrous DMF, and 50 μL of a 9:1 anhydrous DMSO:GBL mixture were combined in a vial producing a bright yellow solution. The vial was heated (operation 119) at 75° C. while stirring for about 90 minutes. HI (57% w/w aqueous solution stabilized with 1.5% H₃PO₂) was added to the precursor solution quickly 5 minutes before sample coating, then the vial was returned to heat. For a 500 μL precursor solution volume, 20 μL HI was used. As a result, the precursor solution changed from yellow color to orange-red, with the color deepening to a rust red over the course of a few minutes.

During preparation of the precursor solution, the PEDOT:PSS-coated substrate that is annealed at operation 111 may be kept in a heated oven as shown by numeral 115.

### (4) Sample Coating Process

150 μL of the orange-red precursor solution was deposited on the PEDOT:PSS coated device and spin-coated (operation 123) at 2000 rpm and 1000 rad/s² clockwise acceleration for 45 seconds at room temperature and resulted in a black coating. Once coated, it was placed in an oven to anneal (operation 127) at 110° C. for 30 minutes under vacuum (e.g., less than 500 milliTorr) after which a thin film of the perovskite-containing composition was formed, and turned pale yellow in color after cooling.

### Performance Testing Processes

Completed devices were prepared for testing by scraping off excess sample from the surface, leaving a stripe of the perovskite-containing composition over all active cells of the substrate (FIG. 2). The testing was performed under ambient conditions in the dark inside a dehumidified shielding box to decrease environmental effects or disturbances. The light source was a 1310 nanometer (nm) laser with a 0.070686 cm² spot size, and a Keithley 2401 source meter provided bias to the system and recorded current outputs. The raw laser output power was measured at 40.1 milliWatts (mW) and was tuned using neutral density optical filters to achieve the desired range of power levels.

### Non-Limiting Results

An example of a photodetector configuration (e.g., device 200) is shown in FIG. 2. The device 200 includes a substrate 201 (e.g., an FTO-coated substrate) that includes a first layer 201a (e.g., glass) and a second layer 201b (the FTO). An HTL 203 (e.g., having a size of about 0.0005 cm²) is in the middle and contains PEDOT:PSS. A perovskite-containing layer 205 is disposed over the HTL 203. The perovskite-containing layer 205 may be a composition, such as a thin film, that includes an all-inorganic perovskite, a nitrogen-containing compound, and an optional mineral acid.

In this example, the HTL 203 has a width (W) of 50 μm and a length (L) of 1 mm. For measurements, needles contact the FTO surface (surface of second layer 201b) on either side of the HTL 203, and the perovskite-containing layer 205 is illuminated via a laser. The energy level diagram corresponding to the device 200 in FIG. 2 is shown in FIG. 3. It is seen that the HOMO of pure CsPbI₃ perovskite lies at −5.8 electron volts (eV), and its lowest unoccupied molecular orbital (LUMO) at −4.09 eV. This bandgap energy of 1.71 eV (2.74×10⁻¹⁹ Joules (J)) is equivalent to a photon of 725 nm light according to Eq. 2:

$$E = hc / λ \qquad ( Eq . 2 )$$

wherein: E refers to energy, h refers to Planck's constant (6.6261×10⁻³⁴ Joule-seconds (J·s)), and c refers to the speed of light (2.9979×10⁸ m/s).

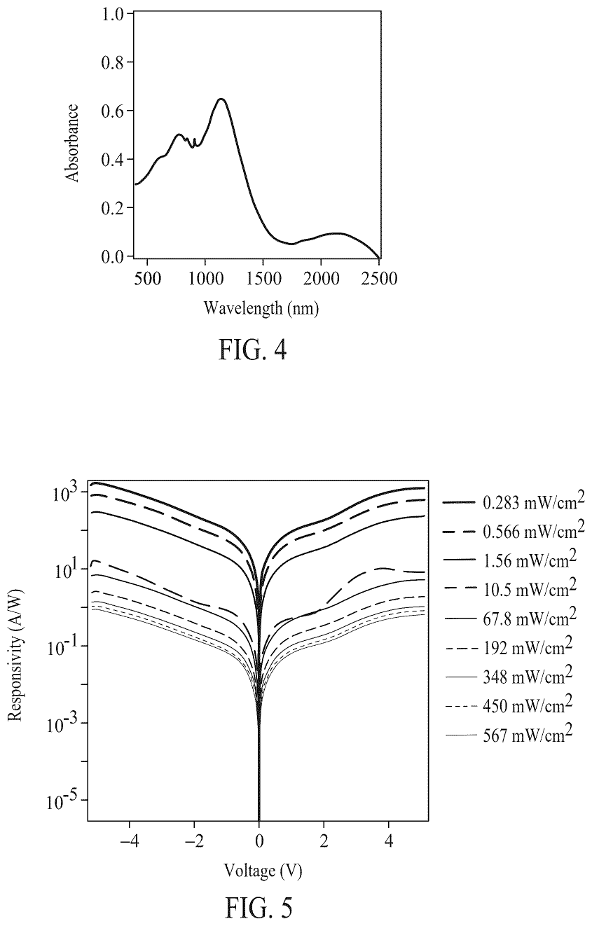

The absorption (at ambient room temperature) of this visible-range photon is supported by the absorption spectrum shown in FIG. 4. Absorption around 725 nm is significant, and the maximum absorption (tallest peak) occurs at about 1132 nm which is in the SWIR range unlike conventional perovskite materials.

This indicates the existence of a second, smaller bandgap in the perovskite-containing composition for SWIR absorption. It is likely that the inclusion of HAI with CsPbI₃ in this novel composition results in a smaller bandgap than pure CsPbI₃, extending its useful range into the infrared region where conventional perovskite photodetectors have failed.

Furthering the investigation into this composition's interaction with SWIR light, FIG. 5 shows the responsivity R of the device under 1310 nm laser illumination at fluence levels ranging from 0.283 milliWatts per square centimeter (mW/cm²) to 567 mW/cm². A very high responsivity of 1650 amperes/watt (A/W) was achieved under a fluence level of 0.283 mW/cm² at a bias of −5 V, indicating exceptional detection even at minute levels of illumination. The lowest power levels achieved the highest responsivities, while higher power levels maintained approximately the same response curve at lower magnitudes. It was found that the curves may be smoother and more consistent under negative bias than under positive bias. Overall, the results shown in FIG. 5 indicate that aspects described herein have excellent responsivity.

Photoresponsivity is a parameter for evaluating the efficacy of a photodetector. Photoresponsivity represents the ratio of output current to incident light power on the active area of a photodetector. Essentially, it represents the ability of a photodetector to convert incoming light into useful electrical signals. This value is calculated using Eq. 3:

$$R = \frac{{I}_{p} - {I}_{d}}{A * P} \qquad ( Eq . 3 )$$

wherein: Iₚ refers to photocurrent, I_{d} refers to dark current, A refers to cell area, and P refers to incident light fluence. Incident light fluence is calculated as the power divided by the spot size of the laser.

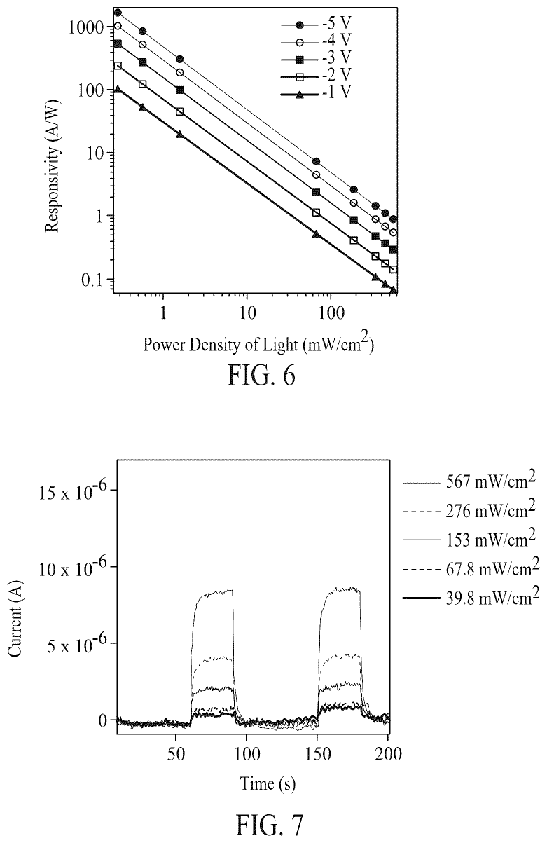

FIG. 6 shows the responsivity of the device as a function of incident light fluence—or power density of light—separated by the bias voltage, from −1 V to −5 V. The negative slope indicates that responsivity decreases dramatically as incident intensity increases. Holding the power density of light constant, the responsivity increases as the magnitude of the bias increases. Overall, the results indicated that perovskite photodetectors described herein exhibit very high responsivity.

External quantum efficiency (EQE) was calculated to further quantify the efficiency of the device. EQE represents the number of free charge carriers generated from the photosensitive material per photon incident upon it. This value may be determined via Eq. 4:

$$EQE = \frac{R * hc}{e λ} \qquad ( Eq . 4 )$$

wherein: R refers to responsivity; h refers to Planck's constant (6.626×10⁻³⁴ J·s), and c refers to speed of light. In the denominator, e refers to elementary charge, or charge of a single electron. The wavelength of the incident light is denoted by λ. Using R=1650 A/W achieved under 0.283 mW/cm² and −5 V bias, the EQE is found to be about 1.48×10³.

The photodetector's response to SWIR light is most visible in FIG. 7. The dark current (light-off current) at each power level has been corrected to approximately 0 amperes to emphasize the increase in generated photocurrent as a function of incident light power. Sharp (and nearly vertical) increases and decreases in current occur as the laser is turned on and off, respectively, with the maximum photocurrent increasing as the incident power increases. The uncorrected dark current visibly increased with time after illumination, indicating that the thermal noise resulting from the SWIR light continues to affect the sample even when the light is off.

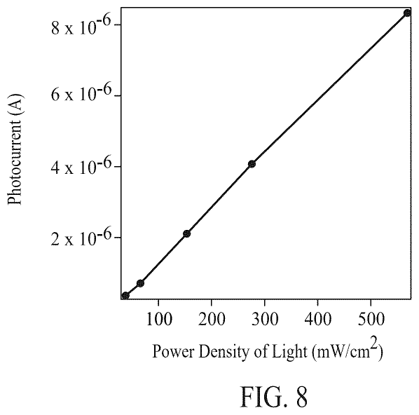

FIG. 8 shows the maximum photocurrent under each illumination level as a function of incident light intensity. The relationship is approximately linear, with a coefficient of determination (R²) greater than 0.999 and a slope of 1.52×10⁻⁸ A/(mW/cm²). As such, the desired photocurrent can be predictably achieved by adjusting the incident light power.

The theoretical photoconductive gain is a parameter for evaluating the efficacy of a photodetector, representing the ratio of photogenerated charge carriers to absorbed incident photons in the material. Under a bias of −5 V and intensity of 0.283 mW/cm², the photoconductive gain is found to be about 1425.

Specific detectivity, represented by D*, is a measure of sensitivity which quantifies the ability of a photodetector to discern weak light signals from noise. Specific detectivity may be calculated using Eq. 5:

$${D}^{*} = \frac{\sqrt{A Δ f} R}{{i}_{n}} = \frac{\sqrt{A Δ f}}{NEP} \qquad ( Eq . 5 )$$

wherein: A refers to active area of the device; Δf in units of Hertz (Hz) refers to bandwidth or the range frequencies over which the device operates; R refers to responsivity (a measure of the device's ability to convert incoming light into electrical signals); and NEP refers to noise equivalent power of the device, which gives the amount of input signal required for the signal-to-noise ratio to be equal to one.

The specific detectivity was determined to be about 7.984×10¹⁰ Jones under −5 V at room temperature in ambient air, indicating that the photodetector performs well.

Aspects of the present disclosure generally relate to a new class of compositions utilized for detecting short-wave infrared (SWIR) light, to devices including the compositions, and to photodetectors including the compositions. Aspects of the present disclosure also generally relate to processes for forming the compositions, the devices, and the photodetectors. As described, the inventors have found an all-inorganic SWIR detector that may include a CsPbI₃ perovskite, HAI as the nitrogen-containing compound, and an optional mineral acid. In some examples, device fabrication includes sequential spin-coating of a room-temperature PEDOT:PSS solution as the HTL, followed by spin-coating of a 75° C. perovskite sample solution. The spin-coating may be performed in ambient conditions, and the annealing may be less than about 150° C. in a standard vacuum oven. As such, devices (e.g., photodetectors) may be made without highly specialized equipment or environmental controls, making them accessible and scalable. Impressively, and in some examples, a responsivity of about 1650 A/W may be achieved under 1310 nm light and −5 V bias at room temperature under a fluence of about 0.283 mW/cm². In some examples, detectors may also display an ultra-high EQE of about 1480 and a gain of about 1425 under −5 V, exemplifying its strong ability to convert incoming photons to charge carriers supplied to the external circuit, which is essential for real-world application. Additionally, and in some examples, detectors may have a specific detectivity of about 7.984×10¹⁰ Jones at room temperature in ambient air, demonstrating the high sensitivity of this material.

### ASPECTS LISTING

The present disclosure provides, among others, the following aspects, each of which may be considered as optionally including any alternate aspects:

Aspect 1. A process for forming a SWIR device, the process comprising:
forming a precursor solution comprising:
   a first compound (AX) comprising a monovalent metal cation (A) and a first monovalent anion (X);
   a second compound (BX₂) comprising a divalent metal (B) and two second monovalent anions (X), each X being the same or different;
   a nitrogen-containing compound or ion thereof; and
   a solvent;
dispersing the precursor solution on a substrate; and
annealing the dispersed precursor solution on the substrate by heating the substrate at an annealing temperature that is from about 50° C. to about 170° C. to form a film composition comprising:
   the nitrogen-containing compound or ion thereof; and
   an all-inorganic perovskite represented by Formula (I):

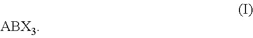

Aspect 2. The process according to aspect 1, wherein the precursor solution comprises: an amount of the second compound (BX₂) in the solvent that is from about 0.1 M to about 1 M; a molar ratio of the first compound (AX) plus the nitrogen-containing compound to the second compound (AX+nitrogen-containing compound:BX₂) is from about 0.5:1 to about 4:1; or combinations thereof.

Aspect 3. The process according to any one of the preceding aspects, wherein the precursor solution further comprises hydroiodic acid or an ion thereof.

Aspect 4. The process according to aspect 3, wherein a molar ratio of the hydroiodic acid or ion thereof to the first compound in the precursor solution is from about 0.01:1 to about 5:1.

Aspect 5. The process according to any one of the preceding aspects, wherein the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

Aspect 6. The process according to any one of the preceding aspects, wherein the solvent comprises dimethylformamide, dimethylsulfoxide, gamma-butyrolactone, tetrahydrofuran, or combinations thereof.

Aspect 7. The process according to any one of the preceding aspects, wherein the solvent comprises dimethylformamide, dimethylsulfoxide, and gamma-butyrolactone.

Aspect 8. The process according to aspect 7, wherein the solvent of the precursor solution comprises: a volume ratio of the dimethylformamide to the dimethylsulfoxide that is from about 5:1 to about 15:1; a volume ratio of the dimethylformamide to the gamma-butyrolactone that is from about 80:1 to about 100:1; and/or a volume ratio of the dimethylsulfoxide to the gamma-butyrolactone that is from about 5:1 to about 13:1.

Aspect 9. The process according to any one of the preceding aspects, wherein, prior to the dispersing the precursor solution on the substrate, the process further comprises: pre-heating the precursor solution at a pre-heating temperature that is from about 40° C. to about 110° C.

Aspect 10. The process according to any one of the preceding aspects, wherein the dispersing the precursor solution on the substrate is performed by spin-coating the precursor solution on the substrate.

Aspect 11. The process according to aspect 10, wherein the spin-coating the precursor solution comprises: rotating the substrate at 100 rpm to about 4,000 rpm; rotating the substrate at an angular acceleration that is from about 100 rad/s² to about 2,000 rad/s²; rotating the substrate for about 5 minutes or less; or combinations thereof.

Aspect 12. The process according to any one of the preceding aspects, wherein the annealing temperature is from about 70° C. to about 150° C.

Aspect 13. The process according to any one of the preceding aspects, wherein the annealing the dispersed precursor solution on the substrate is performed under vacuum.

Aspect 14. A composition, comprising:
a nitrogen-containing compound or ion thereof; and
an all-inorganic perovskite represented by Formula (I):

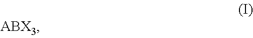

wherein: A of Formula (I) is a monovalent metal or ion thereof; B of Formula (I) is a divalent metal or ion thereof; and each X of Formula (I) is a halogen or ion thereof, each X of Formula (I) being the same or different.

Aspect 15. The composition according to aspect 14, wherein a molar ratio of the nitrogen-containing compound or ion thereof to the all-inorganic perovskite in the composition is from about 0.5:1 to about 4:1.

Aspect 16. The composition according to any one of aspects 14 or 15, wherein: the composition further comprises hydroiodic acid or ion thereof; and/or a molar ratio of the hydroiodic acid or ion thereof to all-inorganic perovskite is from about 0.01:1 to about 5:1.

Aspect 17. The composition according to any one of aspects 14-16, wherein: A of Formula (I) is Cs; B of Formula (I) is Pb; and each X of Formula (I) is, independently, I, Br, Cl, or combinations thereof; and the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

Aspect 18. The composition according to any one of aspects 14-17, wherein the composition has a highest SWIR absorption at room temperature that is from about 700 to about 2800 nm, such as from about 700 nm to about 1800 nm.

Aspect 19. A short-wave infrared detector, comprising:
a thin film comprising a composition, the thin film comprising:
   a nitrogen-containing compound or ion thereof; and
   an all-inorganic perovskite represented by Formula (I):

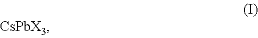

wherein each X of Formula (I) is a halogen or ion thereof, each X of Formula (I) being the same or different; and
wherein a molar ratio of the nitrogen-containing compound or ion thereof to the all-inorganic perovskite in the composition is from about 0.5:1 to about 4:1.

Aspect 20. The short-wave infrared detector according to aspect 19, wherein:
the composition further comprises hydroiodic acid or ion thereof;
the short-wave infrared detector further comprises:
   a substrate comprising glass;
   a hole transport layer disposed above the substrate and below the thin film, the hole transport layer comprising poly(3,4-ethylenedioxythiophene) polystyrene sulfonate; or
combinations thereof.

Where isomers of a named molecule group exist (for example, n-butyl, iso-butyl, sec-butyl, and tert-butyl), reference to one member of the group (for example, n-butyl) shall expressly disclose the remaining isomers (for example, iso-butyl, sec-butyl, and tert-butyl) in the family unless specified to the contrary or the context clearly indicates otherwise. Likewise, reference to a named molecule without specifying a particular isomer (for example, butyl) expressly discloses all isomers (for example, n-butyl, iso-butyl, sec-butyl, and tert-butyl) unless specified to the contrary or the context clearly indicates otherwise. When a compound is described herein such that a particular isomer, enantiomer or diastereomer of the compound is not specified, for example, in a formula or in a chemical name, that description is intended to include each isomer and enantiomer of the compound described individual or in any combination unless specified to the contrary or the context clearly indicates otherwise.

As is apparent from the foregoing general description and the specific aspects, while forms of the aspects have been illustrated and described, various modifications may be made without departing from the spirit and scope of the present disclosure. Accordingly, it is not intended that the present disclosure be limited thereby. Likewise, the term “comprising” is considered synonymous with the term “including.” Likewise whenever a composition, an element, a group of elements, or a method is preceded with the transitional phrase “comprising,” it is understood that we also contemplate the same composition, method. or group of elements with transitional phrases “consisting essentially of,” “consisting of,” “selected from the group of consisting of,” or “Is” preceding the recitation of the composition, element, elements, or method, and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a metal” include aspects comprising one, two, or more metals, unless specified to the contrary or the context clearly indicates only one metal is included.

While the foregoing is directed to aspects of the present disclosure, other and further aspects of the disclosure may be devised without departing from the basic scope thereof, and the scope thereof is determined by the claims that follow.

What is claimed is:

1. A process for forming a short-wave infrared device, the process comprising:
forming a precursor solution comprising:
a first compound (AX) comprising a monovalent metal cation (A) and a first monovalent anion (X);
a second compound (BX₂) comprising a divalent metal (B) and two second monovalent anions (X), each X being the same or different;
a nitrogen-containing compound or ion thereof; and
a solvent;
dispersing the precursor solution on a substrate; and
annealing the dispersed precursor solution on the substrate by heating the substrate at an annealing temperature that is from about 50° C. to about 170° C. to form a film composition comprising:
the nitrogen-containing compound or ion thereof; and
an all-inorganic perovskite represented by Formula (I):

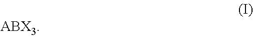

2. The process of claim 1, wherein the precursor solution comprises:
an amount of the second compound (BX₂) in the solvent that is from about 0.1 M to about 1 M;
a molar ratio of the first compound (AX) plus the nitrogen-containing compound to the second compound (AX+nitrogen-containing compound:BX₂) is from about 0.5:1 to about 4:1; or
combinations thereof.

3. The process of claim 1, wherein the precursor solution further comprises hydroiodic acid or an ion thereof.

4. The process of claim 3, wherein a molar ratio of the hydroiodic acid or ion thereof to the first compound in the precursor solution is from about 0.01:1 to about 5:1.

5. The process of claim 1, wherein the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

6. The process of claim 1, wherein the solvent comprises dimethylformamide, dimethylsulfoxide, gamma-butyrolactone, tetrahydrofuran, or combinations thereof.

7. The process of claim 1, wherein the solvent comprises dimethylformamide, dimethylsulfoxide, and gamma-butyrolactone.

8. The process of claim 7, wherein the solvent of the precursor solution comprises:
a volume ratio of the dimethylformamide to the dimethylsulfoxide that is from about 5:1 to about 15:1;
a volume ratio of the dimethylformamide to the gamma-butyrolactone that is from about 80:1 to about 100:1; and
a volume ratio of the dimethylsulfoxide to the gamma-butyrolactone that is from about 5:1 to about 13:1.

9. The process of claim 1, wherein, prior to the dispersing the precursor solution on the substrate, the process further comprises:
pre-heating the precursor solution at a pre-heating temperature that is from about 40° C. to about 110° C.

10. The process of claim 1, wherein the dispersing the precursor solution on the substrate is performed by spin-coating the precursor solution on the substrate.

11. The process of claim 10, wherein the spin-coating the precursor solution comprises:
rotating the substrate at 100 rpm to about 4,000 rpm;
rotating the substrate at an angular acceleration that is from about 100 rad/s² to about 2,000 rad/s²;
rotating the substrate for about 5 minutes or less; or
combinations thereof.

12. The process of claim 1, wherein the annealing temperature is from about 70° C. to about 150° C.

13. The process of claim 1, wherein the annealing the dispersed precursor solution on the substrate is performed under vacuum.

14. A composition, comprising:
a nitrogen-containing compound or ion thereof; and
an all-inorganic perovskite represented by Formula (I): 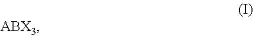
wherein:
A of Formula (I) is a monovalent metal or ion thereof;
B of Formula (I) is a divalent metal or ion thereof; and
each X of Formula (I) is a halogen or ion thereof, each X of Formula (I) being the same or different.

15. The composition of claim 14, wherein a molar ratio of the nitrogen-containing compound or ion thereof to the all-inorganic perovskite in the composition is from about 0.5:1 to about 4:1.

16. The composition of claim 14, wherein:
the composition further comprises hydroiodic acid or ion thereof; and
a molar ratio of the hydroiodic acid or ion thereof to all-inorganic perovskite is from about 0.01:1 to about 5:1.

17. The composition of claim 14, wherein:
A of Formula (I) is Cs;
B of Formula (I) is Pb;
each X of Formula (I) is, independently, I, Br, Cl, or combinations thereof; and
the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, or combinations thereof.

18. The composition of claim 14, wherein the composition has a highest SWIR absorption at room temperature that is from about 700 to about 2800 nm.

19. A short-wave infrared detector, comprising:
a thin film comprising a composition, the thin film comprising:
a nitrogen-containing compound or ion thereof; and
an all-inorganic perovskite represented by Formula (I): 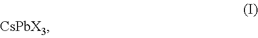
wherein each X of Formula (I) is a halogen or ion thereof, each X of Formula (I) being the same or different; and
wherein a molar ratio of the nitrogen-containing compound or ion thereof to the all-inorganic perovskite in the composition is from about 0.5:1 to about 4:1.

20. The short-wave infrared detector of claim 19, wherein:
the composition further comprises hydroiodic acid or ion thereof;
the short-wave infrared detector further comprises:
a substrate comprising glass;
a hole transport layer disposed above the substrate and below the thin film, the hole transport layer comprising poly(3,4-ethylenedioxythiophene) polystyrene sulfonate; or
combinations thereof.
